(19) United States
(12) Patent Application Publication
(10) Pub. No.: US 2010/0148349 A1
(43) Pub. Date: Jun. 17, 2010

(54) Semiconductor Package Having Support Chip And Fabrication Method Thereof

(75) Inventors: Dong Hee Kim, Seoul (KR); Hyun Oh Yoo, Masan-si (KR); Hyun Woo Lee, Seoul (KR)

Correspondence Address: REINHART BOERNER VAN DEUREN P.C., 2215 PERRYGREEN WAY, ROCKFORD, IL, 61107, US

(73) Assignee: HANA MICRON CO., LTD., Asan-si (KR)

(21) Appl. No.: 12/604,232

(22) Filed: Oct. 22, 2009

(30) Foreign Application Priority Data
Dec. 15, 2008 (KR) 10-2008-0127533

(51) Int. Cl. H01L 25/07; H01L 21/50

(52) U.S. Cl. 257/690; 438/107; 257/E25.018; 257/E21.499; 257/777; 257/787

(57) ABSTRACT

A semiconductor package having a support chip and a fabrication method thereof. The semiconductor package includes a circuit substrate having a conductive pattern on the top surface. A first semiconductor die is attached on top of the circuit substrate. A second semiconductor die is attached on top of the first semiconductor die. Each of the first and second semiconductor dies has a plurality of bond pads on the top surface. A support chip is attached on top of the first semiconductor die and has a plurality of bond pads provided on the top surface. The conductive wires electrically connect the first semiconductor die and the second semiconductor die to the circuit substrate, the second semiconductor die to the support chip, the bond pads of the support chip to each other, and the support chip to the circuit substrate. An encapsulant encloses, as in a capsule, the foregoing components.

### CROSS REFERENCE TO RELATED APPLICATION

The present application claims priority to Korean Patent Application Number 10-2008-00127533 filed on Dec. 15, 2008, the entire contents of which application is incorporated herein for all purposes by this reference.

### BACKGROUND OF THE INVENTION

1. Field of the Invention

The present invention relates to a semiconductor package and a fabrication method thereof, and more particularly, to a stack type semiconductor package, which has a support chip in order to overcome problems associated with wire bonding and molding due to a change in the size of stacked semiconductor chips, and a fabrication method thereof.

2. Description of the Related Art

Nowadays, a Chip Scale Package (CSP) is fabricated by combining chips with several functions according to final purposes. A representative one is the chip stack package, which is produced by stacking several functions of chips one on another. This method involves several techniques such as wafer back-grinding, sawing, semiconductor die attachment, and wire bonding. In several types of the chip stack package, a chip can be combined with different types of chips instead of originally-intended chips for various reasons. This, however, may cause a change in a stable process, thereby creating a defect that is difficult to overcome. While most of the design of a Printed Circuit Board (PCB) is fixed, chips stacked on top of the PCB would vary in their size and in the direction of bonding pads, thereby causing a change in the wire bonding program. This, as a result, causes defects in wire bonding and molding, which did not occur in the existing semiconductor devices. Examples of the defects are caused by the following reasons. First, a very small sized chip is stacked on top of a lower chip having a rather great size and the existing PCB pads are used without being changed. In this case, very long bonding wires are required, which are not originally intended. Second, a different function is pursued by a change in the bonding position without modifying the PCB. Third, a change in the existing stable process may cause obstacles in the way of mass production.

The information disclosed in this Background of the Invention section is only for enhancement of understanding of the background of the invention and should not be taken as an acknowledgment or any form of suggestion that this information forms the prior art that is already known to a person skilled in the art.

### BRIEF SUMMARY OF THE INVENTION

Various aspects of the present invention provide a semiconductor package, which has a support chip in order to overcome the foregoing problems associated with wire bonding and molding due to a change in the size of stacked semiconductor chips, and a fabrication method thereof.

In an aspect of the invention, the semiconductor package may include a circuit substrate, a first semiconductor die, a second semiconductor die, at least one support chip, a plurality of conductive wires, and an encapsulant. The circuit substrate may have a conductive pattern provided on the top surface thereof. The conductive pattern may include a plurality of conductive elements. The first semiconductor die may be attached on top of the circuit substrate and have a plurality of bond pads on the top surface thereof. The second semiconductor die may be attached on top of the first semiconductor die and have a plurality of bond pads on the top surface thereof. At least one support chip may be attached on top of the first semiconductor die and have a plurality of bond pads provided on the top surface thereof. The conductive wires may electrically connect the first semiconductor die to the circuit substrate, the second semiconductor die to the circuit substrate, the second semiconductor die to the support chip, the bond pads of the support chip to each other, and the support chip to the circuit substrate. The encapsulant may enclose, as in a capsule, the first semiconductor die, the second semiconductor die, the support chip, and the conductive wires.

The bond pads on top of the support chip may be spaced apart from each other.

The bond pads on the support chip may be electrically connected to each other by the conductive wires.

The conductive wires may electrically connect the bond pads on the support chip to each other.

In another aspect of the invention, the fabrication method of a semiconductor package may include steps of preparing a circuit substrate having a conductive pattern provided on the top surface thereof, wherein the conductive pattern includes a plurality of conductive elements; attaching a first semiconductor die onto a top surface of the circuit substrate, wherein the first semiconductor die has a plurality of bond pads on the top surface thereof; attaching a second semiconductor die attached onto a top surface of the first semiconductor die, wherein the second semiconductor die has a plurality of bond pads on the top surface thereof; attaching at least one support chip onto a top surface of the first semiconductor die, wherein the support chip has a plurality of bond pads provided on the top surface thereof; electrically connecting the first semiconductor die to the circuit substrate, the second semiconductor die to the circuit substrate, the second semiconductor die to the support chip, the bond pads of the support chip to each other, and the support chip to the circuit substrate by conductive wires; and encapsulating the first semiconductor die, the second semiconductor die, the support chip, and the conductive wires.

The bond pads on the support chip may be electrically connected to each other by the conductive wires, and the bond pads on the support chip may be electrically connected to the bond pads on the second semiconductor die.

According to exemplary embodiments of the invention, the problems associated with wire bonding and molding can be overcome by the attachment of the support chip.

The methods and apparatuses of the present invention have other features and advantages which will be apparent from or are set forth in more detail in the accompanying drawings, which are incorporated herein, and the following Detailed Description of the Invention, which together serve to explain certain principles of the present invention.

### BRIEF DESCRIPTION OF THE DRAWINGS

FIG. 1A is a cross-sectional view illustrating a semiconductor package having a support chip in accordance with an exemplary embodiment of the invention;

FIG. 1B is a top plan view of the semiconductor package shown in FIG. 1A;

FIG. 2A is a cross-sectional view illustrating a semiconductor package having a support chip in accordance with another exemplary embodiment of the invention;

FIG. 2B is a top plan view of the semiconductor package shown in FIG. 2A;

FIG. 3A is a cross-sectional view illustrating a semiconductor package having a support chip in accordance with a further exemplary embodiment of the invention;

FIG. 3B is a top plan view of the semiconductor package shown in FIG. 3A;

FIG. 4 is a flowchart illustrating a fabrication method of a semiconductor package having a support chip in accordance with an exemplary embodiment of the invention; and

FIGS. 5A through 5F are cross-sectional views sequentially illustrating the fabrication method shown in FIG. 4.

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

Above all, reference should be made to the drawings, in which the same reference numerals and signs are used throughout the different drawings to designate the same or similar components.

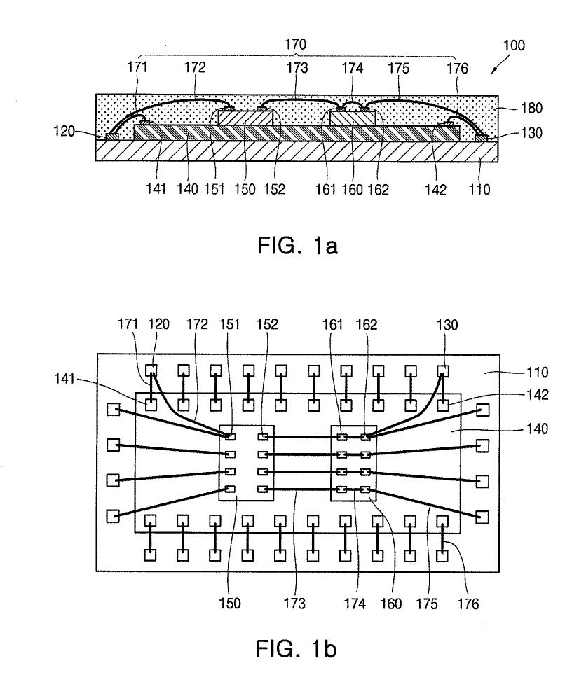

FIGS. 1A and 1B are a cross-sectional view and a top plan view illustrating a semiconductor package 100 having a support chip in accordance with an exemplary embodiment of the invention.

First, referring to FIG. 1A, the semiconductor package having a support chip 100 includes a circuit substrate 110, a first semiconductor die 140, a second semiconductor die 150, a support chip 160, a plurality of conductive wires 170, and an encapsulant 180.

The circuit substrate 110 has conductive patterns 120 and 130, each of which is composed of a plurality of conductive elements. The conductive patterns 120 and 130 can be made of, but not limited to, Cu, Au, Ag, Pd, metal alloys, or an equivalent thereof.

The first semiconductor die 140 is bonded onto the top surface of the circuit substrate 110, and is provided with a plurality of bond pads 141 and 142 on the top surface thereof. The first semiconductor die 140 can be bonded onto the circuit substrate 110 by an adhesive (not shown) applied to the top surface of the circuit substrate 110. The adhesive can be implemented with, but not limited to, an epoxy resin, a silicone resin, an acrylic resin, a double sided tape, or the like. The first semiconductor die 140 is basically made of silicone, inside of which a plurality of semiconductor elements can be provided. The bond pads 141 and 142 are provided on top of the first semiconductor die 140. While the bond pads 141 and 142 are illustrated as protruding outwards for the sake of convenience, they can also be provided inside the first semiconductor die 140. The bond pads 141 and 142 can be provided on the edge or central portion of the top surface of the first semiconductor die 140. In addition, the bond pads 141 and 142 are parts where an electrical connection is established to input/output electrical signals to/from the first semiconductor die 140. The bond pads 141 and 142 can be made of Al.

The second semiconductor die 150 is bonded on top of the first semiconductor die 140, and is provided with a plurality of bond pads 151 and 152 on the top surface thereof. The second semiconductor die 150 is sized smaller than the first semiconductor die 140, and has a configuration substantially the same as the first semiconductor die 140. Accordingly, a further description of the second semiconductor die 150 will be omitted.

The support chip 160 is bonded on top of the first semiconductor die 140, and is provided with a plurality of bond pads 161 and 162 on the top surface thereof. The bond pads 161 and 162 are spaced apart from each other. In addition, the bond pads 161 and 162 can be made of the same material as the bond pads 151 and 152, which are provided on top of the first semiconductor die 140. The support chip 160 is not implemented with a semiconductor element, and can be made of silicone or glass, or of the same material as the circuit substrate 110.

The conductive wires 170 include conductive wires 171 and 176 electrically connecting the first semiconductor die 140 to the circuit substrate 110, conductive wires 172 electrically connecting the second semiconductor die 150 to the circuit substrate 110, conductive wires 173 electrically connecting the second semiconductor die 150 to the support chip 160, conductive wires 174 electrically connecting together the bond pads 161 and 162 of the support chip 160, and conductive wires 175 electrically connecting the support chip 160 to the circuit substrate 110. The conductive wires 170 can be made of, but not limited to, Au, Al, Cu, or an equivalent thereof.

The encapsulant 180 encloses, as in a capsule, the first semiconductor die 140, the second semiconductor die 150, the support chip 160, and the conductive wires 170. The encapsulant 180 encloses all of the first semiconductor die 140, the second semiconductor die 150, the support chip 160, and the conductive wires 170 in order to protect them from the external environment. The encapsulant 180 can be made of, but not limited to, an epoxy compound encapsulated by a mold, a liquid encapsulating material distributed by a dispenser, or an equivalent thereof.

Referring to FIG. 1B, the semiconductor package having a support chip 100 is viewed from above. The circuit substrate 110 is surrounded by the conductive patterns 120 and 130 along the outer circumference thereof, the first semiconductor die 140 is bonded on top of the circuit substrate 110, and the second semiconductor die 150 and the support chip 160 are bonded on top of the semiconductor die 140. In addition, the first semiconductor die 140 is electrically connected to the circuit substrate 110 by the conductive wires 171, the second semiconductor die 150 is electrically connected to the circuit substrate 110 by the conductive wires 172, the second semiconductor die 150 is electrically connected to the support chip 160 by the conductive wires 173, the bond pads 161 and 162 of the support chip 160 are electrically connected to each other by the conductive wires 174, the support chip 160 is electrically connected to the circuit substrate 110 by the conductive wires 175, and the first conductive die 140 is electrically connected to the circuit substrate 110 by the conductive wires 176.

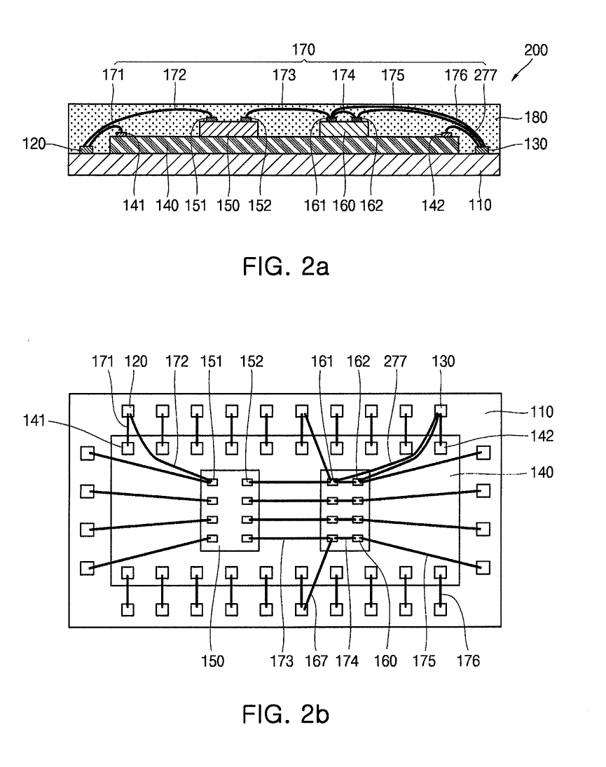

FIGS. 2A and 2B are a cross-sectional view and a top plan view illustrating a semiconductor package 200 having a support chip in accordance with another exemplary embodiment of the invention.

First, referring to FIG. 2A, the semiconductor package 200 can be configured substantially the same as the semiconductor package 100. However, unlike the semiconductor package 100, the semiconductor package 200 also includes conductive wires 277, 167 electrically connecting a bond pad 161 on top of a support chip 160 to a conductive pattern 130 on the circuit substrate 110. Specifically, the bond pad 161 on the top surface of the support chip 160 is electrically connected to a conductive element of the conductive pattern 130 by the conductive wire 277, and a bond pad 162 on the top surface of the support chip 160 is electrically connected to the same conductive element of the conductive pattern 130 by a conductive wire 277.

Next, referring to FIG. 2B, the semiconductor package 200 is viewed from above. One bond pad 161 and one bond pad 162 are electrically connected to one conductive element of the conductive pattern 130 of the circuit substrate 110.

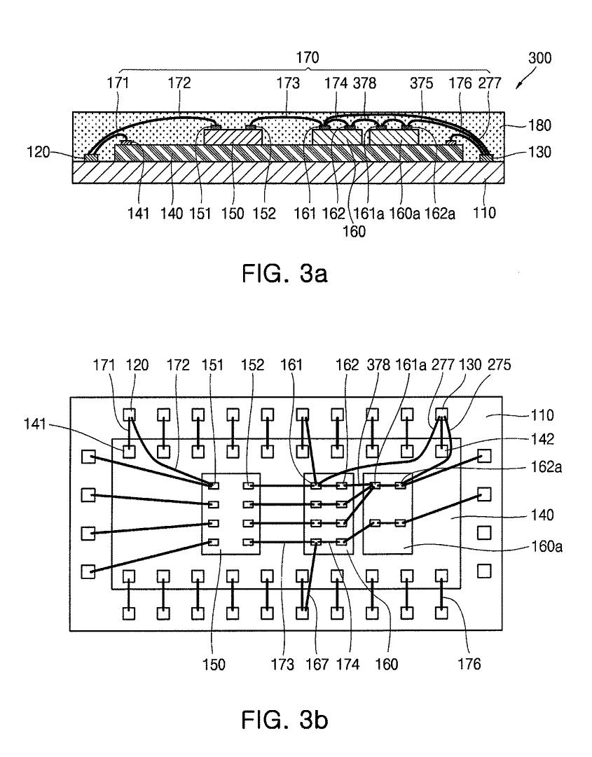

FIGS. 3A and 3B are a cross-sectional view and a top plan view illustrating a semiconductor package 300 in accordance with a further exemplary embodiment of the invention.

First, referring to FIG. 3A, the semiconductor package 300 includes two support chips 160 and 160a. A bond pad 162 of the support chip 160 is electrically connected to a bond pad 161a of the support chip 160a by a conductive wire 378. The semiconductor package 300 can be configured substantially the same as the semiconductor package 100.

Referring to FIG. 3B, the semiconductor package 300 is viewed from above. The semiconductor package 300 includes the two support chips 160 and 160a. One bond pad 161 of the support chip 160 is electrically connected to a conductive element of a conductive pattern 130 of a circuit substrate 110 by a conductive wire 277, and one bond pad 162a of the support chip 160a is electrically connected to the same conductive element of the conductive pattern 130 of the circuit substrate 110 by a conductive wire 275. The two support chips 160 and 160a are electrically connected to each other by conductive wires 378. While the semiconductor package 300 has been illustrated as having the two support chips 160 and 160a on top of the circuit substrate 110, it is not intended to limit the number of support chips.

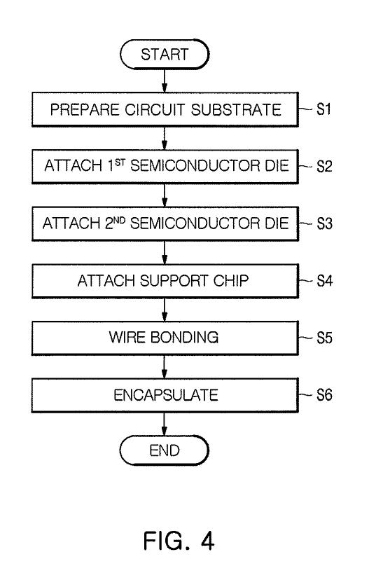

FIG. 4 is a flowchart illustrating a fabrication method of a semiconductor package having a support chip in accordance with an exemplary embodiment of the invention.

Referring to FIG. 4, the fabrication method of the semiconductor package 100 in accordance with one exemplary embodiment of the invention includes circuit substrate preparation step S1, first semiconductor die attachment step S2, second semiconductor die attachment step S3, support chip attachment step S4, wire bonding step S5, and encapsulation step S6.

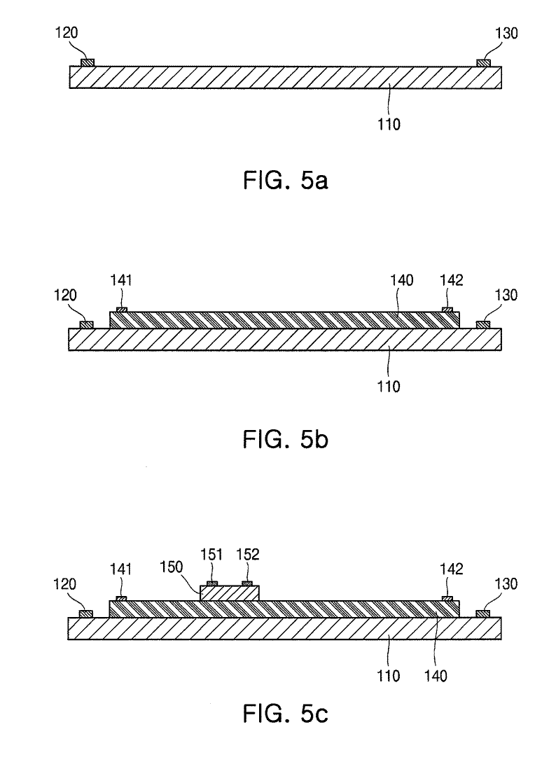

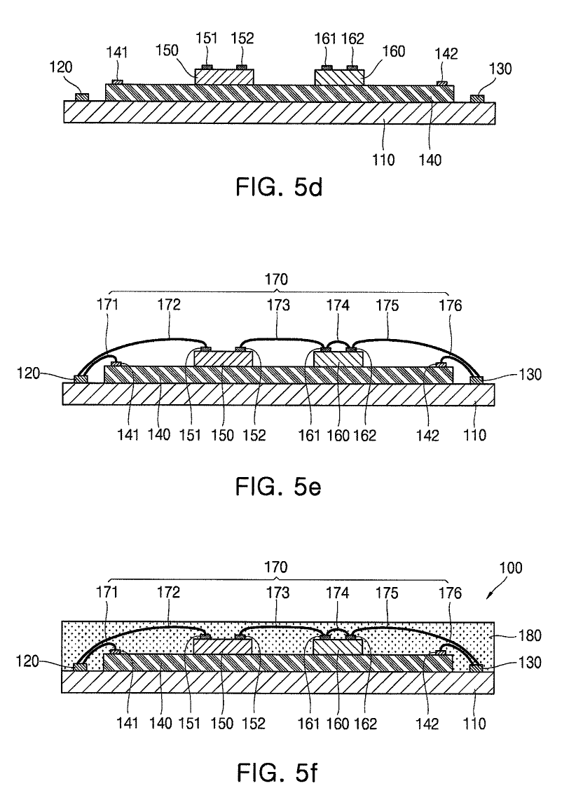

The fabrication method of the semiconductor package 100 in accordance with one exemplary embodiment of the invention will be described more fully hereinafter with reference to FIGS. 5A through 5F.

FIGS. 5A through 5F are cross-sectional views sequentially illustrating the fabrication method of the semiconductor package in accordance with one exemplary embodiment of the invention.

First, referring to FIG. 5A, the circuit substrate preparation step S1 of FIG. 4 is shown. In the circuit substrate preparation step S1, the circuit substrate 110 has conductive patterns 120 and 130 on the top surface thereof. Each of the patterns 120 and 130 is composed of a plurality of conductive elements.

Then, referring to FIG. 5B, the first semiconductor die attachment step S2 of FIG. 4 is shown. In the first semiconductor die attachment step S2, the first semiconductor die 140 having the bond pads 141 and 142 is bonded on top of the circuit substrate 110. The circuit substrate 110 is loaded into a reaction chamber, where an adhesive is applied with a thickness from 2 μm to 3 μm over the upper surface of the circuit substrate 110 in a nitrogen atmosphere, at a temperature ranging from 200° C. to 360° C. Afterwards, the first semiconductor die 140 is attached onto the circuit substrate 110, followed by cooling. The adhesive can be implemented with an epoxy resin, a silicone resin, an acrylic resin, a double sided tape, or the like.

Then, referring to FIG. 5C, the second semiconductor die attachment step S3 is shown. In the second semiconductor die attachment step S3, the second semiconductor die 150 having the bond pads 151 and 152 are attached onto the top surface of the first semiconductor die 140. The second semiconductor die attachment step S3 can be carried out in the same attachment method as the first semiconductor die attachment step S2.

Sequentially, referring to FIG. 5D, the support chip attachment step S4 is shown. In the support chip attachment step S4, the support chip 160 having the bond pads 161 and 162 is attached onto the top surface of the first semiconductor die 140. The support chip 160 can be attached in the same manner as the second semiconductor die 150.

Afterwards, referring to FIG. 5E, the wire bonding step S5 is shown. In the wire bonding step S5, the first semiconductor die 140 is electrically connected to the circuit substrate 110 by the conductive wires 171 and 176, the second semiconductor die 150 is electrically connected to the circuit substrate 110 by the conductive wires 172, the second semiconductor die 150 is electrically connected to the support chip 160 by the conductive wires 173, the bond pads 161 are electrically connected to the bond pads 162 of the support chip 160 by the conductive wires 174, and the support chip 160 is electrically connected to the circuit substrate 110 by the conductive wires 175. The conductive wires 170 can be made of, but not limited to, Au, Al, Cu, or an equivalent thereof. Available examples of the wire bonding may include, but not limited to, ball bonding, wedge bonding, bump reverse bonding, etc. The ball bonding includes bonding one end of a wire by forming a ball at one end, bending the wire with a predetermined loop height, and stitch-bonding the other end of the wire to the lead frame. The characteristics of the ball bonding are to increase the height of a ball without biasing the ball. The wedge bonding can advantageously reduce work effort and fabrication costs by directly wedge-bonding a wire onto a bonding pad of the same material without an additional process. In addition, the bump reverse bonding includes forming a bump on a semiconductor die pad, followed by ball bonding onto a lead, and then stitch bonding onto the bump. The wire bonding step S5 of this embodiment can preferably employ, but not limited to, the ball bonding in order to easily control the direction of the conductive wires 170 to be connected.

Next, referring to FIG. 5F, the encapsulation step S6 is shown. In the encapsulation step S6, the first semiconductor die 140, the second semiconductor die 150, the support chip 160, and the conductive wires 170 are enclosed by the encapsulant 180.

The encapsulant 180 can be formed, preferably, at a high temperature atmosphere in the range from 170° C. to 180° C. The encapsulant 180 can be formed using a mold, dispenser, or an equivalent, which can be varied or modified according to the type and purpose of the semiconductor package having a support chip. In other words, the encapsulation is not limited thereto. Furthermore, the encapsulation 180 can be made of, but not limited to, an epoxy compound, a liquid encapsulating material, or an equivalent thereof.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the claims appended hereto and their equivalents.

What is claimed is:

1. A semiconductor package comprising:
a circuit substrate having a conductive pattern provided on a top surface thereof, wherein the conductive pattern includes a plurality of conductive elements;
a first semiconductor die attached on top of the circuit substrate, wherein the first semiconductor die has a plurality of bond pads on a top surface thereof;
a second semiconductor die attached on top of the first semiconductor die, wherein the second semiconductor die has a plurality of bond pads on a top surface thereof;
at least one support chip attached on top of the first semiconductor die, wherein the semiconductor chip has a plurality of bond pads provided on a top surface thereof;
a plurality of conductive wires electrically connecting the first semiconductor die to the circuit substrate, the second semiconductor die to the circuit substrate, the second semiconductor die to the support chip, the bond pads of the support chip to each other, and the support chip to the circuit substrate; and
an encapsulant enclosing, as in a capsule, the first semiconductor die, the second semiconductor die, the support chip, and the conductive wires.

2. The semiconductor package in accordance with claim 1, wherein the bond pads on the support chip are spaced apart from each other.

3. The semiconductor package in accordance with claim 1, wherein the bond pads on the support chips are electrically connected to each other by the conductive wires.

4. The semiconductor package in accordance with claim 1, wherein the conductive wires electrically connect the bond pads on the support chip to each other.

5. A fabrication method of a semiconductor package, comprising:
preparing a circuit substrate having a conductive pattern provided on a top surface thereof, wherein the conductive pattern includes a plurality of conductive elements;
attaching a first semiconductor die onto a top surface of the circuit substrate, wherein the first semiconductor die has a plurality of bond pads on a top surface thereof;
attaching a second semiconductor die attached onto a top surface of the first semiconductor die, wherein the second semiconductor die has a plurality of bond pads on a top surface thereof;
attaching at least one support chip onto a top surface of the first semiconductor die, wherein the semiconductor chip has a plurality of bond pads provided on a top surface thereof;
electrically connecting the first semiconductor die to the circuit substrate, the second semiconductor die to the circuit substrate, the second semiconductor die to the support chip, the bond pads of the support chip to each other, and the support chip to the circuit substrate by conductive wires; and
encapsulating the first semiconductor die, the second semiconductor die, the support chip, and the conductive wires.

6. The fabrication method in accordance with claim 5, comprising electrically connecting the bond pads on the support chip to each other and electrically connecting the bond pads on the support chip to the bond pads on the second semiconductor die by the conductive wires.
